(19) United States
(12) Patent Application Publication
(10) Pub. No.: US 2012/0211464 A1
(43) Pub. Date: Aug. 23, 2012

(54) METHOD OF MANUFACTURING PRINTED CIRCUIT BOARD HAVING METAL BUMP

(75) Inventors: Jin Yong AN, Daejeon (KR); Ki Hwan Kim, Gyunggi-do (KR)

(73) Assignee: SAMSUNG ELECTRO-MECHANICS CO., LTD., Suwon (KR)

(21) Appl. No.: 13/457,792

(22) Filed: Apr. 27, 2012

Related U.S. Application Data
(62) Division of application No. 12/379,480, filed on Feb. 23, 2009.

(30) Foreign Application Priority Data
Dec. 8, 2008 (KR) 10-2008-0124152

(51) Int. Cl. H05K 3/00; C23F 1/02

(52) U.S. Cl. 216/13; 427/96.1; 427/98.4

(57) ABSTRACT

A method of manufacturing a printed circuit board, including: providing a metal layer; forming an insulation layer on the metal layer and then forming via holes for exposing the metal layer in the insulation layer; forming vias charged in the via holes and a circuit layer on the insulation layer; and forming metal bumps at ends of the vias.

### CROSS-REFERENCE TO RELATED APPLICATIONS

This application is a U.S. divisional application filed under 37 CFR 1.53(b) claiming priority benefit of U.S. Ser. No. 12/379,480 filed in the United States on Feb. 23, 2009, which claims earlier priority benefit to Korean Patent Application No. 10-2008-0124152 filed with the Korean Intellectual Property Office on Dec. 8, 2008, the disclosures of which are incorporated herein by reference.

### BACKGROUND

1. Field

The present invention relates to a printed circuit board comprising a metal bump and a method of manufacturing the same, and, more particularly, to a printed circuit board comprising metal bumps, which have constant diameters and can be arranged at fine pitches because it is directly connected to the end of a via without using additional bump pads, and a method of manufacturing the same.

2. Description of the Related Art

With the advancement of electronics industry, electronic parts have become highly functionalized, and thus a package (PKG) is required to be miniaturized and highly-densified. Further, an interposer (substrate) for connecting an IC to a main board is also required to be highly-densified. The densification of the package is caused by the increase in the number of I/Os, and methods of connecting the package with the interposer have improved. Currently, as a method of mounting an IC in a high-density package, a wire bonding method and a flip bonding method are used. Among them, the flip bonding method may be used due to the costs required to mount the IC when the number of I/Os is increased.

FIG. 1A-1M are sectional views showing a conventional process of manufacturing a substrate on which a semiconductor chip is mounted.

First, as shown in FIG. 1A, a carrier 1 formed of a double-sided copper clad laminate is provided, and then, as shown in FIG. 1B, a solder resist 3 is applied on the carrier 1, and then, as shown in FIG. 1C, a dry film 5 is applied on the solder resist 3 and then patterned. Thereafter, as shown in FIG. 1D, electrolytic plating is conducted, and then, as shown in FIG. 1E, the dry film 5 is removed to form connection pads 7. Subsequently, as shown in FIG. 1F, a first insulation layer 9 is formed on the connection pads 7 and the solder resist 3, and then, as shown in FIG. 1G, a first circuit layer 11 is formed.

Thereafter, as shown in FIG. 1H, a build-up layer 13 is additionally formed by repeating the above processes, and then, as shown in FIG. 1I, a solder resist 15 is applied on the build-up layer 13.

Subsequently, as shown in FIG. 1J, the carrier 1 is separated by conducting a routing process, and then, as shown in FIG. 1K, copper foil is etched and removed. Then, as shown in FIG. 1L, the solder resists 3 and 15 are patterned to form openings 17 for exposing the connection pads 7.

Thereafter, as shown in FIG. 1M, solder balls 19 for flip chip bonding are formed in the openings 17. The formation of the solder balls 9 is conducted through a solder paste printing process using screen printing and a reflow process.

However, as described above, the method of forming a bump on a printed circuit board using a printing process is problematic in that large connection pads are required, and thus it is difficult to realize bumps arranged at fine pitches of 120 μm or less.

Further, the method of forming a bump on a printed circuit board using a printing process is problematic in that a fine bump is not formed, or its volume is very small even though the fine bump is formed.

Further, in the method, since the connection pads are formed by plating, their thicknesses are different from each other due to plating deviation, and, since solder paste cannot be easily printed in a completely uniform manner even in the solder paste printing process, the heights of solder balls are not uniform, so that there is a problem in that solder balls which are not connected to a semiconductor chip are formed.

Further, in the method, since the stepped portion of the solder resist 15 is large, there is a problem in that voids are formed in an underfill process performed after the mounting of an electronic part.

### SUMMARY

Accordingly, the present invention has been made to solve the above conventional problems, and the present invention provides a printed circuit board comprising a metal bump, the metal bump having fine pitches and uniform diameter and height, and a method of manufacturing the same.

An aspect of the present invention provides a printed circuit board, including: metal bumps having constant diameters and protruding over an insulation layer; a circuit layer formed beneath the insulation layer; and vias passing through the insulation layer to connect the metal bumps with the circuit layer.

The printed circuit board may further include a build-up layer disposed beneath the insulation layer and including a lower circuit layer electrically connected to the circuit layer.

In the printed circuit board, the via may be configured such that its diameter is decreased toward the metal bump from an inner surface of the insulation layer.

In the printed circuit board, the lower circuit layer may include connection pads, and the printed circuit board may further include a solder resist layer covering the lower circuit layer and having openings for exposing the connection pads.

Another aspect of the present invention provides a method of manufacturing a printed circuit board, including: providing a metal layer; forming an insulation layer on the metal layer and then forming via holes for exposing the metal layer in the insulation layer; forming vias charged in the via holes and a circuit layer on the insulation layer; and forming metal bumps at ends of the vias.

In the method, the metal layer in providing the metal layer may be provided in a state in which it is placed on a carrier in the providing of the metal layer, and the method may further include: separating the metal layer from the carrier before the forming of metal bumps.

The method may further include: forming a build-up layer including a lower circuit layer on the insulation layer after the forming of the vias and the circuit layer.

In the method, the forming of the vias and the circuit layer may include: forming a seed layer on inner surfaces of the via holes and the insulation layer; forming a plating resist layer including openings for exposing the via holes and openings for forming the circuit layer on the seed layer; plating the openings for exposing the via holes and the openings for forming the circuit layer to form the vias and the circuit layer; and removing the exposed portion of the seed layer.

In the method, the forming of the metal bumps may include: applying an etching resist on the metal layer and patterning the etching resist; and etching the metal layer exposed from the etching resist through a reactive ion etching process to form the metal bumps.

In the method, the forming of the metal bumps may include: applying a plating resist including openings for forming metal bumps on the metal layer; plating the openings for forming metal bumps to form the metal bumps; and etching and removing the exposed portion of the metal layer.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1M are sectional views showing a conventional process of manufacturing a substrate on which a semiconductor chip is mounted;

FIG. 2 is a sectional view showing a printed circuit board including a metal bump according to an embodiment of the present invention;

FIGS. 3 to 13 are sectional views showing a method of manufacturing a printed circuit board including a metal bump according to an embodiment of the present invention;

FIGS. 14 to 17 are sectional views showing a method of manufacturing a printed circuit board including a metal bump according to another embodiment of the present invention;

FIG. 18 is a sectional view showing a printed circuit board mounting an electronic part; and

FIG. 19 is a sectional view showing a printed circuit board mounting an electronic part, in which solder connections are additionally formed on respective metal bumps.

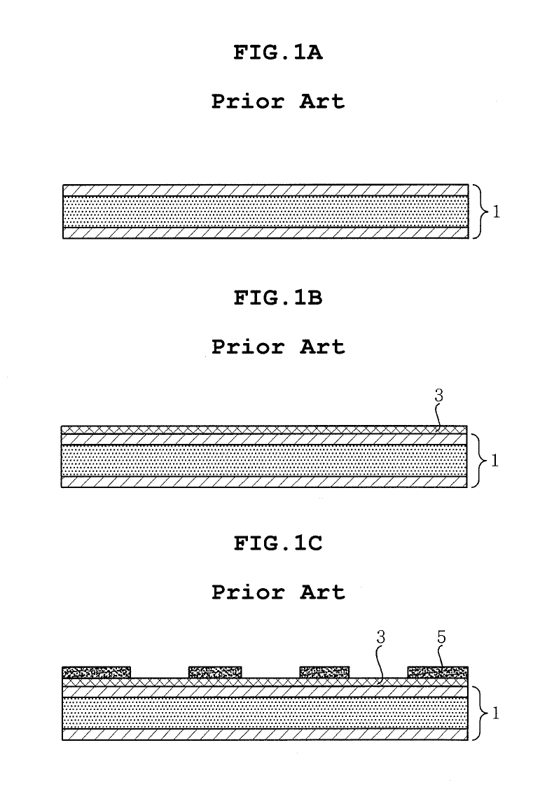

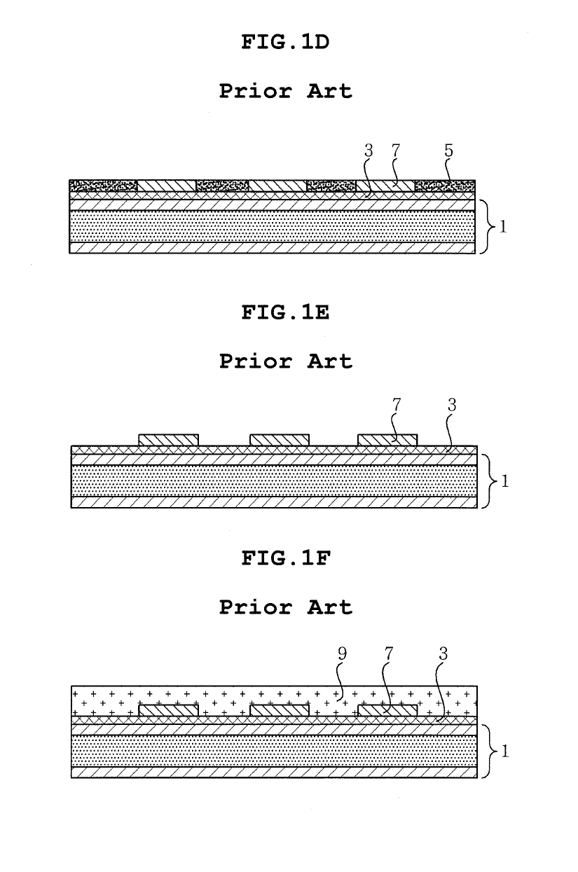

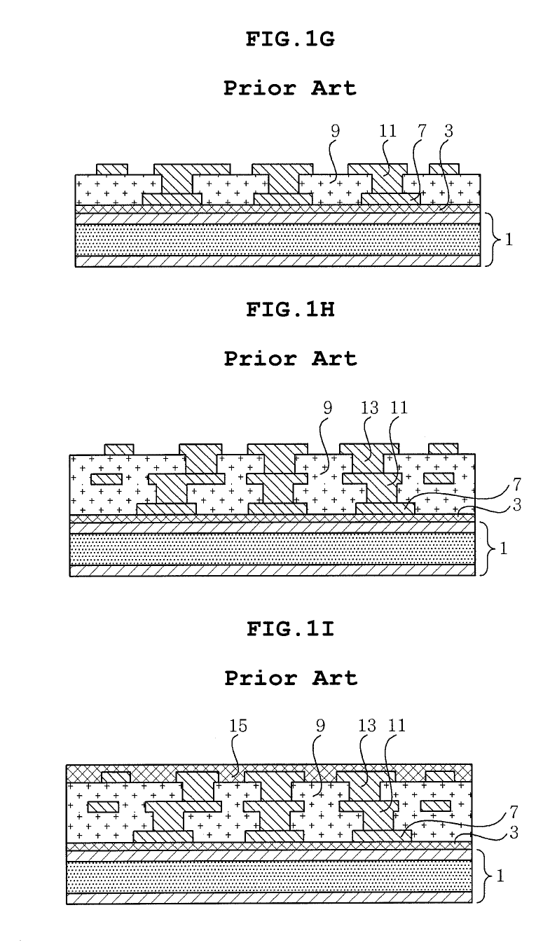

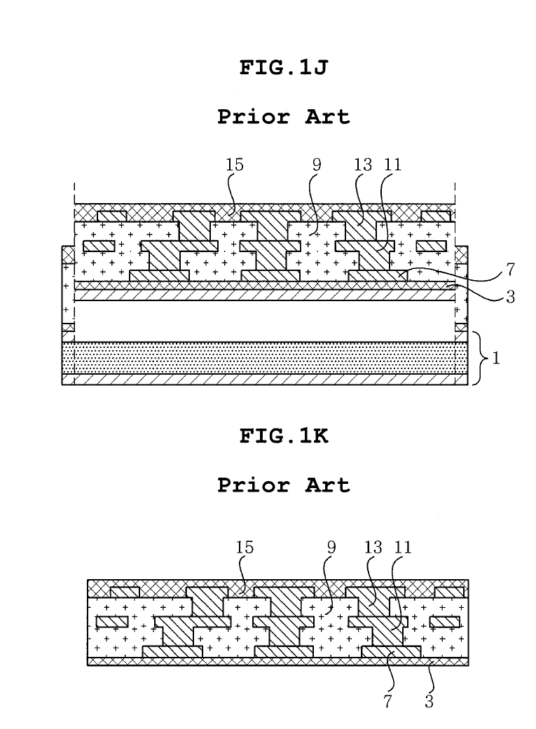

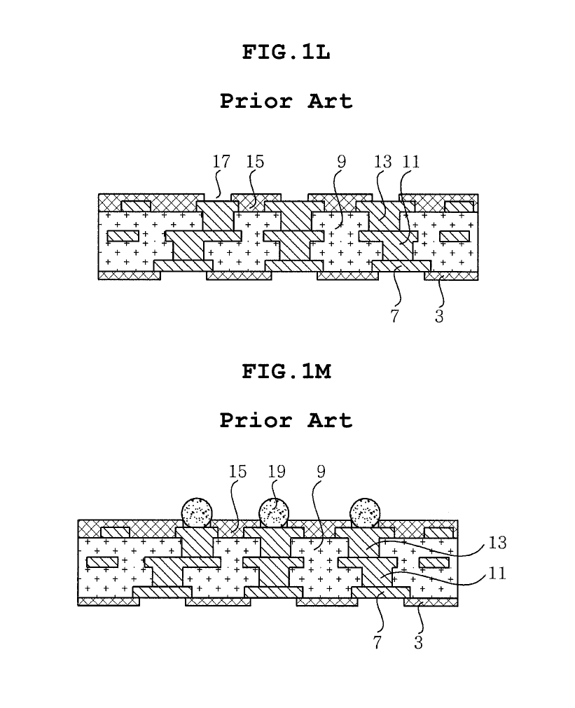

### DESCRIPTION OF EMBODIMENTS

Hereinafter, preferred embodiments of the present invention will be described in detail with reference to the attached drawings.

Throughout the accompanying drawings, the same reference numerals are used to designate the same or similar components, and redundant descriptions thereof are omitted. In the following description, the terms “upper”, “lower” and the like are used to differentiate a certain component from other components, but the configuration of such components should not be construed to be limited by the terms.

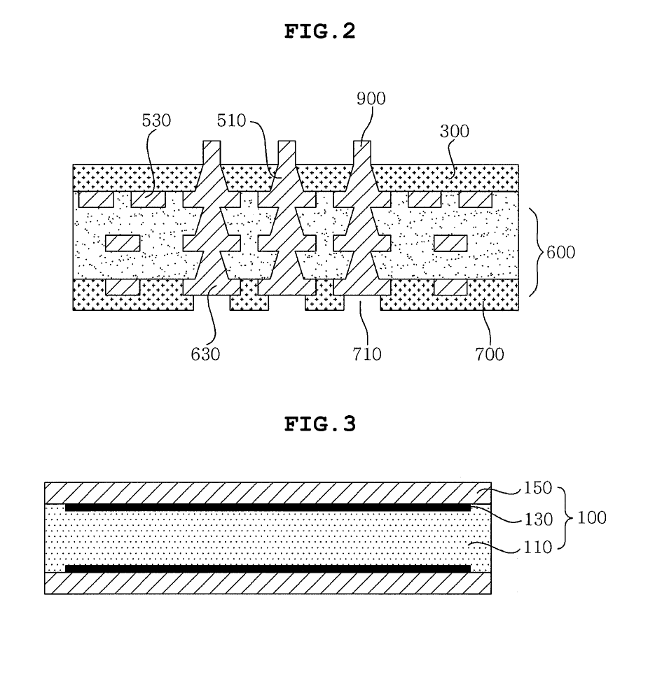

FIG. 2 is a sectional view showing a printed circuit board including a metal bump according to an embodiment of the present invention. As shown in FIG. 2, the printed circuit board according to an embodiment of the present invention includes an insulation layer 300, metal bumps 900 having constant diameters and protruding over the insulation layer 300, a circuit layer 530 formed beneath the insulation layer 300, and vias 510 passing through the insulation layer and electrically connecting the metal bumps 900 with the circuit layer 530.

The insulation layer 300 may be a solder resist layer, and may be made of a composite polymer resin which is generally used as an interlayer insulation material. For example, the insulation layer 300 may be made of prepreg, or an epoxy resin such as FR-4, BT (Bismaleimide Triazine), ABF (Ajinomoto Build up Film) or the like, but the present invention is not limited thereto.

The circuit layer 530 is formed beneath the insulation layer 300 and is formed of an electrically conductive metal pattern for transmitting electric signals. The circuit layer 530 may be made of a conductive metal such as gold, silver, copper, nickel or the like.

The metal bumps 900 protrude over the insulation layer 300 and function to electrically connect an electronic part 1000 (refer to FIG. 18) to be mounted in the printed circuit board later with the circuit layer 530. In this embodiment, each of the metal bumps 900 has a post shape in which its upper diameter is the same as its lower diameter. Here, the meaning that the metal bump 900 has a constant diameter does not mean that the upper and lower diameters of the metal bump 900 are mathematically exactly equal to each other but means that the slight change in diameter of the metal bump 900 due to errors occurring in a substrate manufacturing process is allowed.

The vias 510 are formed by charging a conductive metal into via holes 310 passing through the insulation layer 300, and serve to electrically connect the metal bumps 900 with the circuit layer 530. The via may be made of a conductive metal, preferably, the same metal as the circuit layer 530. In this case, the via is configured such that its diameter is decreased toward the metal bump 900 from the inner surface of the insulation layer 300. That is, the metal bump 900 is integrated with the surface of the via 510, the surface having a minimum diameter, and bump pads are not additionally required.

Meanwhile, in this embodiment, only the upper structure of the printed circuit board, which is a characteristic structure of the present invention, is described, but the printed circuit board according to the embodiment of the present invention further includes a build-up layer 600 which is disposed beneath the insulation layer 300 and includes a lower circuit layer 630 electrically connected to the circuit layer 530. The build-up layer 600 may further include an inner circuit layer formed between the circuit layer 530 and the lower circuit layer 630. In this embodiment, only one inner circuit layer is exemplified, but the number of the inner circuit layers is not limited. It is easily understood by those skilled in the art that, if necessary, the number of the inner circuit layers can be controlled.

In this case, the lower circuit layer 630 may include connection pads, and may further include a solder resist layer 700 covering the lower circuit layer 630 and having openings 710 for exposing the connection pads.

Since the above printed circuit board includes the post-shaped metal bumps 900 having excellent electrical conductivity, the printed circuit board can be easily connected electrically to an electronic part 1000 mounted thereon.

Further, the printed circuit board is advantageous in that the printed circuit board includes metal bumps 900 arranged at fine pitches because the metal bumps 900 have constant diameters, the lower diameters of which are not larger than the upper diameters thereof, and are directly connected to the ends of vias 510 without using additional bump pads.

FIGS. 3 to 13 are sectional views showing a method of manufacturing a printed circuit board including a metal bump according to an embodiment of the present invention. Hereinafter, the method of manufacturing a printed circuit board including a metal bump according to an embodiment of the present invention will be described with reference to FIGS. 3 to 13.

First, a process of providing a metal layer 150 will be described. In this embodiment, as shown in FIG. 3, a carrier 100 includes a substrate 110 composed of a double-sided copper clad laminate and an insulating material, a release layer 130 formed on the substrate 110, and a metal layer 150 formed on the release layer 130. The carrier 100 functions as a support used to prevent a printed circuit board from warping during processing. The release layer 130 has a length and an area smaller than those of the substrate 110, and may be formed on the substrate 110, but not on the lateral sides of the substrate 110. This release layer 130 serves to easily separate the metal layer 150 from the carrier 100 in the latter half of a process of manufacturing a printed circuit board.

Here, the release layer 130 may be formed using a releasing material through a thin film coating process or a sputtering process. The metal layer 150 may be made of a conductive metal such as copper (Cu), gold (Au), silver (Ag) or the like. In this embodiment, copper foil having a thickness of 30˜100 μm is used as the metal layer 150.

In this embodiment, a process of forming layering components on both sides of the carrier 100 is exemplified, but a process of forming the layering components on one side of the carrier 100 may be performed.

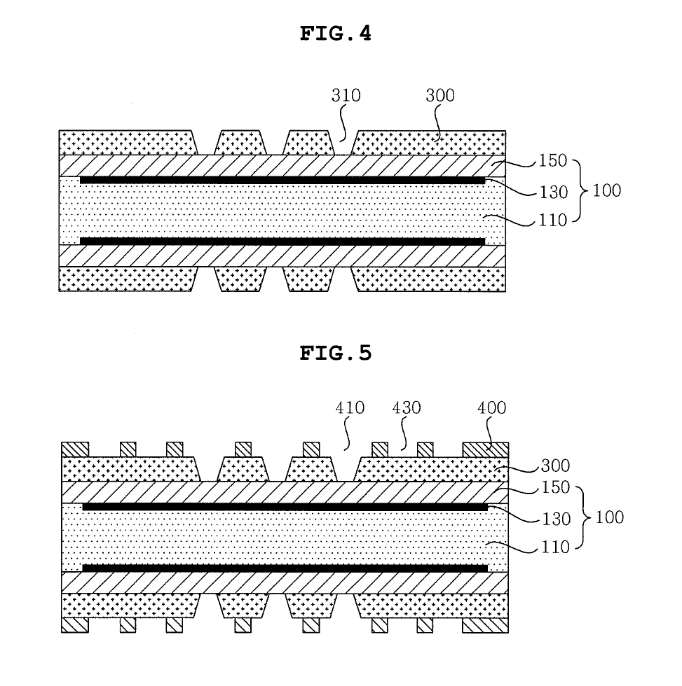

Subsequently, as shown in FIG. 4, an insulation layer 300 is placed on the metal layer 150, and then via holes for exposing the metal layer 150 are formed in the insulation layer 300. The insulation layer 300 may be made of a composite polymer resin which is generally used as an interlayer insulation material. For example, the insulation layer 300 may be made of prepreg, or an epoxy resin such as FR-4, BT (Bismaleimide Triazine), ABF (Ajinomoto Build up Film) or the like, but, in this embodiment, the insulation layer 300 is made of a solder resist.

The via holes 310 may be formed using a YAG laser drill or a CO2 laser drill.

Next, a process of forming a circuit layer 530 and vias 510 charged in via holes 310 will be described. First, a seed layer (not shown) is formed on the insulation layer 300 and the inner surfaces of the via holes 310. The process of forming the seed layer is a pre-treatment process of electrolytic plating to be performed later.

Subsequently, as shown in FIG. 5, a plating resist layer 400, including openings 410 for exposing the via holes 310 and openings for forming the circuit layer 530, is formed on the seed layer. The plating resist layer 400 may be formed of a photosensitive dry film, and may be patterned by selectively exposing and curing the applied plating resist using a mask having light shielding patterns and then removing the uncured portion of the plating resist.

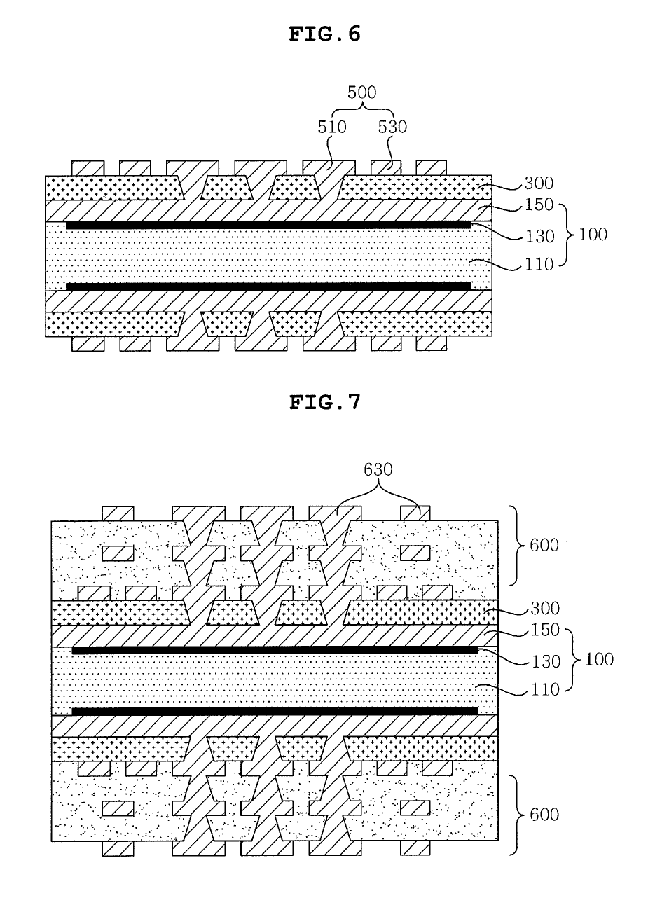

Subsequently, as shown in FIG. 6, the openings 410 and 430 of the plating resist layer 400 are plated, and then the exposed portion of the seed layer is removed to form the vias 510 and the circuit layer 530. The vias 510 and the circuit layer 530 are formed using the seed layer as a lead wire by electrolytic plating, and then the exposed portion of the seed layer is removed by flash etching or quick etching.

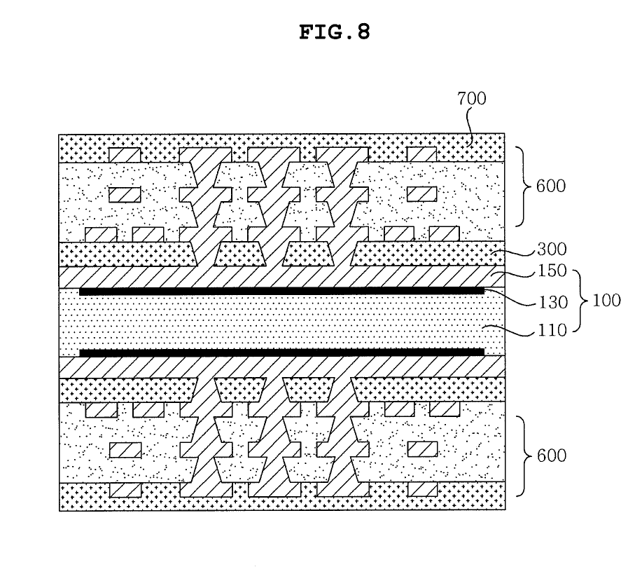

Subsequently, as shown in FIG. 7, a build-up layer 600 including a lower circuit layer 630 is formed on the insulation layer 300. The build-up layer 600 may be formed through a semi-additive process including the application of an insulating material, the formation of via holes and the plating of circuit pattern, and the process of forming the build-up layer will not be described in detail. When the lower circuit layer 630 is completed, as shown in FIG. 8, a solder resist layer 700 for covering the lower circuit layer 630 is formed. In this embodiment, a two-layered build up layer including one inner circuit layer and one lower circuit layer is described, but the number of the circuit layers is not limited thereto.

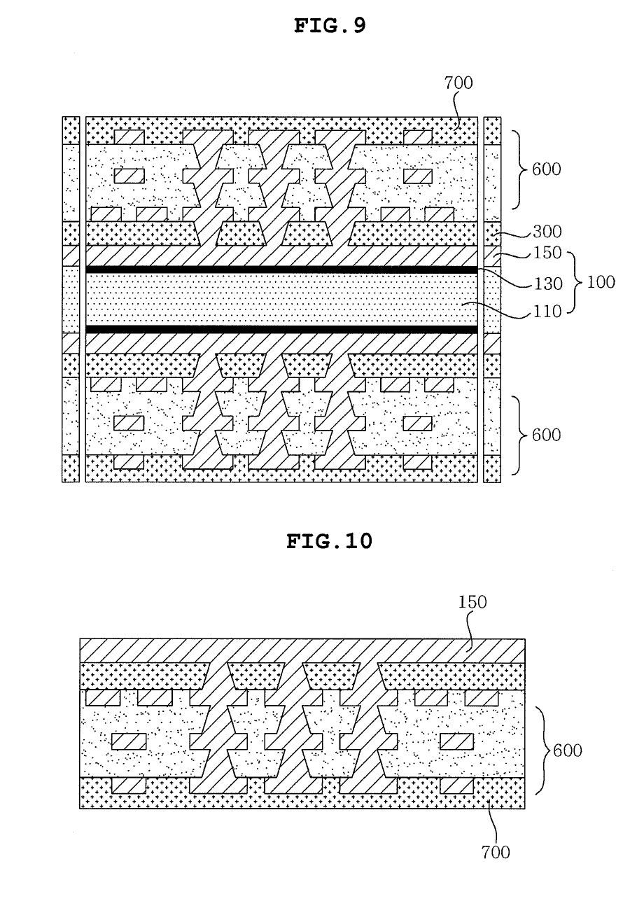

Subsequently, as shown in FIG. 9, the metal layer 150 is separated from the carrier 100. Specifically, the metal layer 150 may be separated from the carrier by cutting the lateral portions of the carrier 100 and the printed circuit board placed on the carrier 100 through a routing process. Here, the routing process is a process of performing mechanical cutting using a routing bit. In the routing process, the lateral portions of the carrier 100 and the printed circuit board are cut and removed, and thus the metal layer 150 is separated from the substrate 110 constituting the carrier 100 by the release layer 130.

Next, a process of forming metal bumps 900 connected with the ends of the vias 510 will be described.

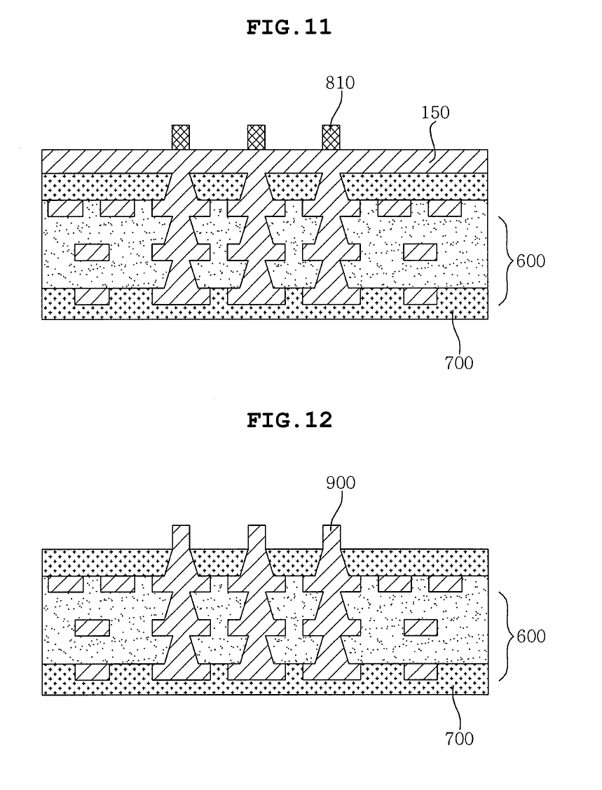

When the metal layer 150 is separated from the carrier 100 as shown in FIG. 10, as shown in FIG. 11, an etching resist 810 is applied on the metal layer 150 and then patterned. The etching resist 810 may be a photosensitive dry film.

Subsequently, as shown in FIG. 12, the metal layer 150 exposed from the etching resist 810 is removed to form the metal bumps 900. The metal bumps 900 is generally formed using a metal etchant through a wet etching process, but may be formed through a reactive ion etching process.

The reactive ion etching process is a dry etching process of forming etching gas into plasma gas and then allowing the plasma gas to collide with an electroactive polymer using upper and lower electrodes. In this reactive ion etching process, etching is performed by the combination of physical impact and chemical reaction. According to the wet etching process, the metal bump 900 has a shape in which its lateral sides are tapered, whereas, according to the reactive ion etching process, it is possible to form the metal bump 900 having a constant diameter, that is, having a post shape in which its lateral sides are not tapered.

Here, the meaning that the metal bump 900 has a constant diameter does not mean that the upper and lower diameters of the metal bump 900 are mathematically exactly equal to each other but means that a slight change in diameters of the metal bumps 900 due to the errors occurring in a substrate manufacturing process is allowed.

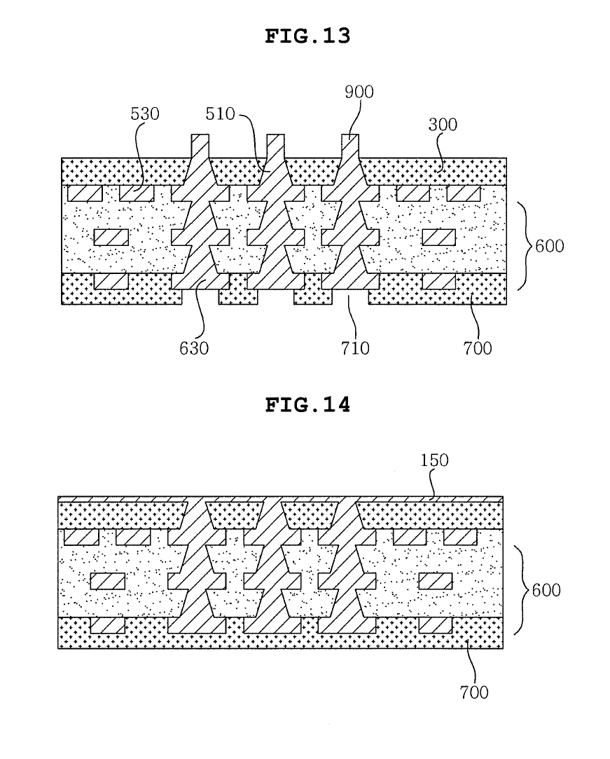

Subsequently, as shown in FIG. 13, openings 710 for exposing lower connection pads are formed in the solder resist layer 700 formed on the lower circuit layer 630.

Thereafter, solder connections may be additionally formed on the metal bumps 900. The surface of the lower connection pad may be OSP (Organic Solderability Preservative) treated or an electroless nickel immersion gold (ENIG) layer may be formed on the lower connection pad.

FIGS. 14 to 17 are sectional views showing a method of manufacturing a printed circuit board including a metal bump according to another embodiment of the present invention. Hereinafter, the method of manufacturing a printed circuit board including a metal bump according to another embodiment of the present invention will be described with reference to FIGS. 12 to 22. Here, parts of the description overlapping with those of the above embodiment are omitted.

First, a process of providing a metal layer 150 will be described. In this embodiment, the metal layer 150 is a seed metal layer having a thickness of 1˜3 μm, and a seed copper foil is used as the seed metal layer.

Since the process of forming vias 510 and the circuit layer 530 and the process of forming the build-up layer are the same as or similar to the above embodiment, the description of these processes is omitted, and only the process of forming the metal bumps 900 will be described.

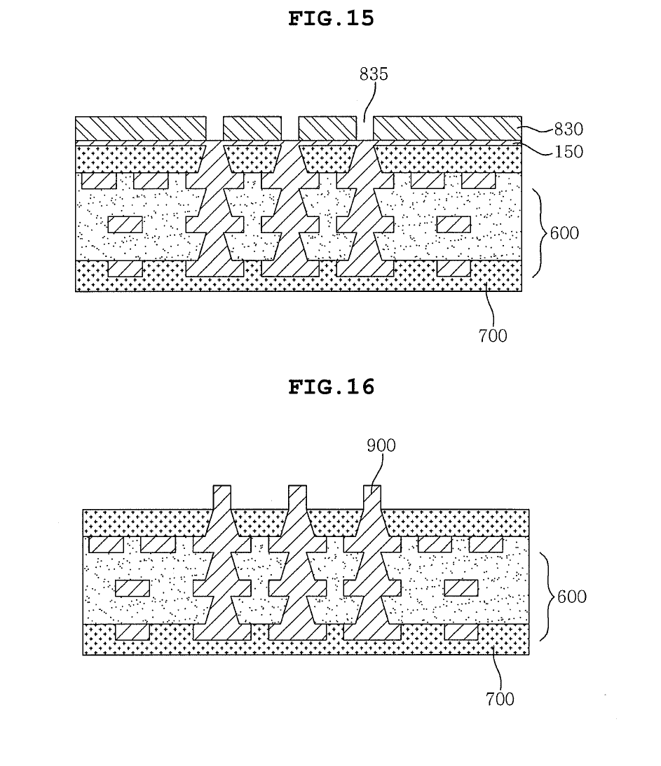

When the metal layer 150 is separated from the carrier 100 as shown in FIG. 14, as shown in FIG. 15, a plating resist 830 provided therein with openings 835 for forming the metal pumps 900 is applied on the metal layer 150. The plating resist 830 may be a photosensitive dry film.

Subsequently, as shown in FIG. 16, the openings 835 of the plating resist 830 is plated to form metal bumps 900, and then the exposed portion of the metal layer 150 is etched and removed. The metal bumps 900 are formed using the metal layer as a lead wire through electrolytic plating, and the exposed portion of the metal layer 150 is removed by flash etching or quick etching.

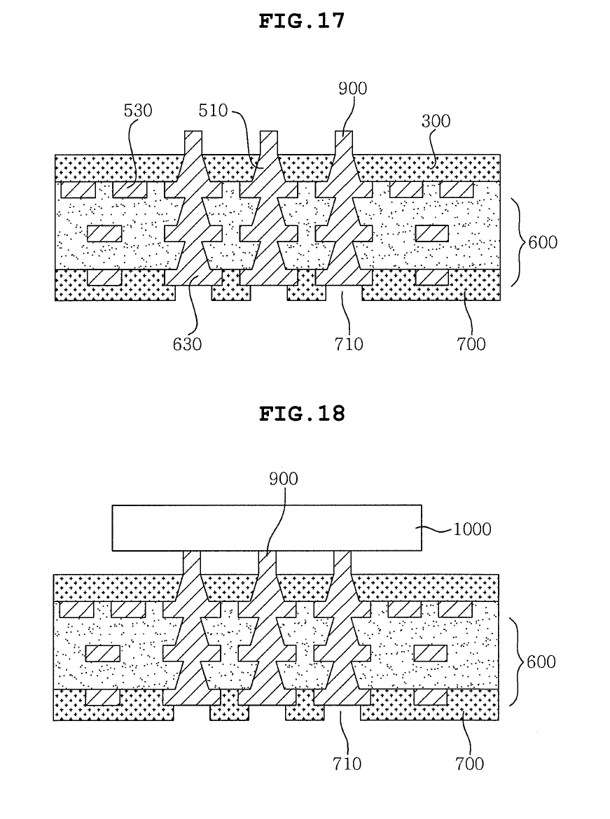

Subsequently, as shown in FIG. 17, openings 710 for exposing lower connection pads are formed in a solder resist layer 700.

According to the above process of manufacturing a printed circuit board, since metal bumps 900 are formed using the metal layer 150 placed on the carrier 100, a printed circuit board including post-shaped metal bumps having constant height and excellent electrical conductivity can be manufactured.

Further, according to the above process of manufacturing a printed circuit board, since metal bumps 900 are formed by a reactive ion etching process or a semi-additive process, metal bumps having constant diameters can be formed, and thus metal bumps arranged at fine pitches can also be formed

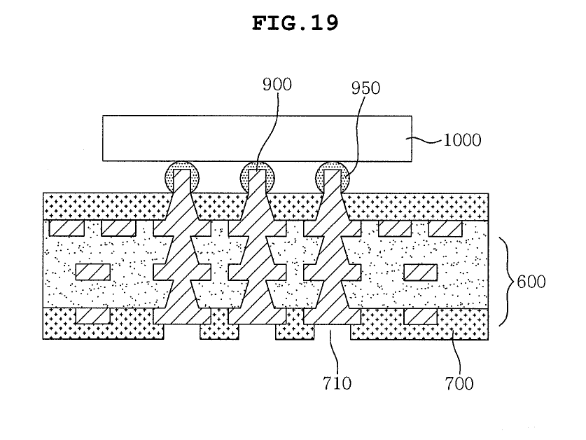

FIG. 18 is a sectional view showing a printed circuit board mounting an electronic part 1000, and FIG. 19 is a sectional view showing a printed circuit board mounting an electronic part 1000, in which solder connections are additionally formed on respective metal bumps 900.

As described above, since the printed circuit board according to the present invention includes the metal bumps 900 arranged at fine pitches, it can be easily connected with a small-sized electronic part 1000 having many I/O.

As described above, the printed circuit board according to the present invention is advantageous in that the printed circuit board can be electrically connected to electronic parts mounted therein easily because the printed circuit board includes post-shaped metal bumps having excellent electrical conductivity.

Further, the printed circuit board according to the present invention is advantageous in that the printed circuit board includes metal bumps arranged at fine pitches because the metal bumps have constant diameters, i.e. the lower diameters of which are not larger than the upper diameters thereof, and are directly connected to the ends of vias without additional bump pads being used.

Further, the printed circuit board according to the present invention is advantageous in that voids are not formed in an underfill process because a solder resist layer has no stepped portion.

According to the process of manufacturing a printed circuit board of the present invention, since metal bumps are formed using a metal layer placed on a carrier, a printed circuit board including post-shaped metal bumps having constant heights and excellent electrical conductivity can be manufactured.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing a printed circuit board, comprising:
providing a metal layer;
forming an insulation layer on the metal layer and then forming via holes for exposing the metal layer in the insulation layer;
forming vias charged in the via holes and a circuit layer on the insulation layer; and
forming metal bumps at ends of the vias.

2. The method according to claim 1, wherein the metal layer in providing the metal layer is provided in a state in which it is placed on a carrier in the providing of the metal layer, and
wherein before forming the metal bumps, further comprises separating the metal layer from the carrier before the forming of the metal bumps.

3. The method according to claim 1, after forming the vias and the circuit layer, further comprising:
forming a build-up layer including a lower circuit layer on the insulation layer after the forming of the vias and the circuit layer.

4. The method according to claim 1, wherein the forming of the vias and the circuit layer comprises:
forming a seed layer on inner surfaces of the via holes and the insulation layer including;
forming a plating resist layer including openings for exposing the via holes and openings for forming the circuit layer on the seed layer;
plating the openings for exposing the via holes and the openings for forming the circuit layer to form the vias and the circuit layer; and
removing an exposed portion of the seed layer.

5. The method according to claim 1, wherein the forming of the metal bumps comprises:
applying an etching resist on the metal layer and patterning the etching resist; and
etching the metal layer exposed from the etching resist through a reactive ion etching process to form the metal bumps.

6. The method according to claim 1, wherein the forming of the metal bumps comprises:
applying a plating resist including openings for forming metal bumps on the metal layer;
plating the openings for forming metal bumps to form the metal bumps; and
etching and removing the exposed portion of the metal layer
